(19) United States
(12) Patent Application Publication
(10) Pub. No.: US 2015/0092636 A1
(43) Pub. Date: Apr. 2, 2015

(54) SINGLE LOCAL OSCILLATOR ARCHITECTURE

(71) Applicant: Broadcom Corporation, Irvine, CA (US)

(72) Inventors: Ahmadreza Rofougaran, Newport Coast, CA (US); Maryam Rofougaran, Rancho Palos Verdes, CA (US); Alireza Zolfaghari, Laguna Niguel, CA (US)

(21) Appl. No.: 14/069,431

(22) Filed: Nov. 1, 2013

Related U.S. Application Data
(60) Provisional application No. 61/884,852, filed on Sep. 30, 2013.

(51) Int. Cl. H04B 1/40; H04J 1/08; H03L 7/099; H04L 5/14

(52) U.S. Cl. CPC H04B 1/403; H04L 5/14; H04J 1/085; H03L 7/0992
USPC 370/281; 375/219

(57) ABSTRACT

A system and method in a transceiver for reducing power. In transmission mode (Tx), a local oscillator (LO) generator (LOGEN) circuit modifies a PLL oscillation signal that runs at a fraction of the carrier signal. In the receive mode (Rx), the LOGEN circuit increases power consumption unnecessarily and is bypassed in favor of a PLL output which is a multiple of the carrier signal.

### CROSS REFERENCE TO RELATED PATENTS

The present U.S. Utility patent application claims priority pursuant to 35 U.S.C. §119(e) to U.S. Provisional Patent Application Ser. No. 61/884,852, entitled “Single Local Oscillator Architecture” filed Sep. 30, 2013, pending, which is hereby incorporated herein by reference in its entirety and made part of the present U.S. Utility patent application for all purposes.

### BACKGROUND

1. Technical Field

The present disclosure described herein relates generally to wireless communications and more particularly to local oscillator architecture in a wireless communication device.

2. Description of Related Art

Communication systems are known to support wireless and wire line communications between wireless and/or wire line communication devices. The communication systems range from national and/or international mobile/handheld systems to the point-to-point gaming, in-home wireless networks, audio, video wireless devices. Communication systems typically operate in accordance with one or more communication standards. Wireless communication systems operate in accordance with one or more standards including, but not limited to, IEEE 802.11, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, smartphone, two-way radio, tablet, personal digital assistant (PDA), personal computer (PC), laptop computer, home entertainment equipment, RFID reader, RFID tag, et cetera communicates directly or indirectly with other wireless communication devices. For each wireless communication device to participate in wireless communications, it includes a built-in radio transceiver (i.e., receiver and transmitter) or is coupled to an associated radio transceiver (e.g., a station for in-home and/or in-building wireless communication networks, RF modem, etc.). As is known, the receiver is coupled to one or more antennas (e.g., MIMO) and may include one or more low noise amplifiers, one or more intermediate frequency stages, a filtering stage, and a data recovery stage. The low noise amplifier(s) receives inbound RF signals via the antenna and amplifies them. The one or more intermediate frequency stages mix the amplified RF signals with one or more local oscillations to convert the amplified RF signal into baseband signals or intermediate frequency (IF) signals. The filtering stage filters the baseband signals or the IF signals to attenuate unwanted out-of-band signals to produce filtered signals. The data recovery stage recovers raw data from the filtered signals in accordance with the particular wireless communication standard.

As is also known, the transmitter includes a data modulation stage, one or more intermediate frequency stages, and a power amplifier. The data modulation stage converts raw data into baseband signals in accordance with a particular wireless communication standard. The one or more intermediate frequency stages mix the baseband signals with one or more local oscillations to produce RF signals. With current communications standards using gigahertz range operating frequencies, it is becoming increasingly more difficult to design transceivers that avoid pulling (pulling oscillator off frequency). This is especially problematic in transceivers that receive and transmit using similar frequencies.

### BRIEF DESCRIPTION OF THE DRAWING(S)

FIG. 1 is a schematic block diagram of an embodiment of a wireless communication system;

FIG. 2 is a schematic block diagram of another embodiment of a wireless communication system;

FIG. 3 is a schematic block diagram of an RF transceiver for a wireless communication system;

FIG. 4 illustrates a general PLL architecture diagram in accordance with the present disclosure;

FIG. 5 illustrates an embodiment of a dual-band transceiver architecture in accordance with the present disclosure;

FIG. 6 illustrates an aspect embodiment of a Bluetooth transceiver with a PLL/LOGEN circuit in accordance with the present disclosure;

FIG. 7 illustrates an aspect embodiment of a dual-band transceiver including a dual path transmitter in accordance with the present disclosure;

FIG. 8 illustrates another embodiment of transceiver architecture with a single LO for frequency-division duplexing (FDD) in accordance with the present disclosure;

FIG. 9 illustrates another embodiment of transceiver architecture with a single LO for frequency-division duplexing (FDD) in accordance with the present disclosure; and

FIG. 10 illustrates a dual path transmitter for constant envelope and non-constant envelope modes in accordance with the present disclosure.

### DETAILED DESCRIPTION

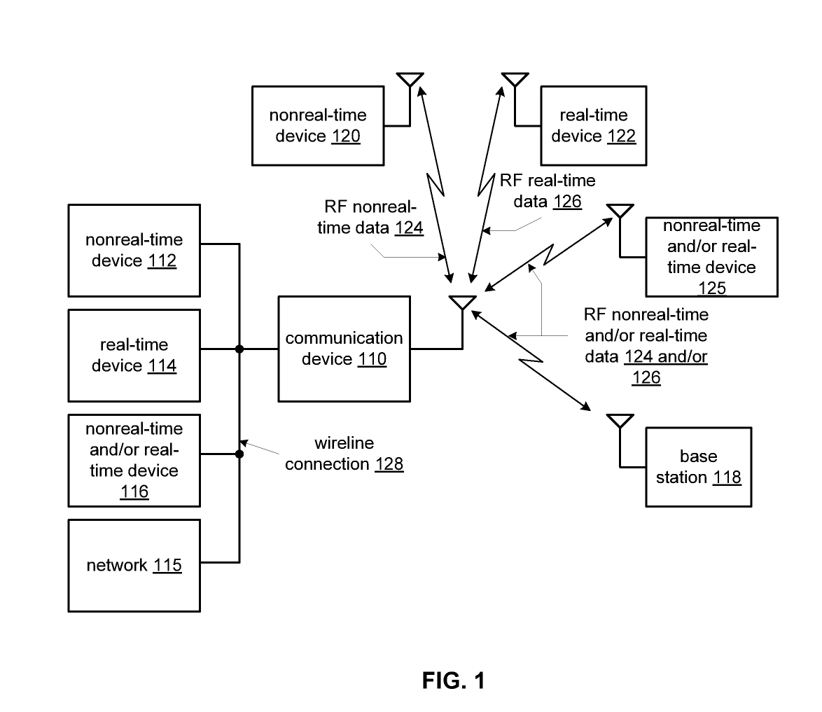

FIG. 1 is a schematic block diagram of a communication system in accordance with the technology described herein. In particular, a communication system is shown that includes a communication device 110 that communicates real-time data 126 and/or non-real-time data 124 wirelessly with one or more other devices such as base station 118, non-real-time device 120, real-time device 122, and non-real-time and/or real-time device 125. In addition, communication device 110 can also optionally communicate over a wireline connection with network 115, non-real-time device 112, real-time device 114, and non-real-time and/or real-time device 116.

In an embodiment of the present invention the wireline connection 128 can be a wired connection that operates in accordance with one or more standard protocols, such as a universal serial bus (USB), Institute of Electrical and Electronics Engineers (IEEE) 488, IEEE 1394 (Firewire), Ethernet, small computer system interface (SCSI), serial or parallel advanced technology attachment (SATA or PATA), or other wired communication protocol, either standard or proprietary. The wireless connection can communicate in accordance with a wireless network protocol such as WiHD, NGMS, IEEE 802.11a, ac, b, g, n, or other 802.11 standard protocol, Bluetooth, Ultra-Wideband (UWB), WIMAX, or other wireless network protocol, a wireless telephony data/voice protocol such as Global System for Mobile Communications (GSM), General Packet Radio Service (GPRS), Enhanced Data Rates for Global Evolution (EDGE), Personal Communication Services (PCS), or other mobile wireless protocol or other wireless communication protocol, either standard or proprietary. Further, the wireless communication path can include separate transmit and receive paths that use separate carrier frequencies and/or separate frequency channels. Alternatively, a single frequency or frequency channel can be used to bi-directionally communicate data to and from the communication device 110.

Communication device 110 can be a mobile phone such as a cellular telephone, a local area network device, personal area network device or other wireless network device, a personal digital assistant, game console, personal computer, laptop computer, or other device that performs one or more functions that include communication of voice and/or data via wireline connection 128 and/or the wireless communication path. Further communication device 110 can be an access point, base station or other network access device that is coupled to a network 115 such at the Internet or other wide area network, either public or private, via wireline connection 128. In an embodiment of the present invention, the real-time and non-real-time devices 112, 114 116, 118, 120, 122 and 125 can be personal computers, laptops, PDAs, mobile phones, such as cellular telephones, devices equipped with wireless local area network or Bluetooth transceivers, FM tuners, TV tuners, digital cameras, digital camcorders, or other devices that either produce, process or use audio, video signals or other data or communications.

In operation, the communication device includes one or more applications that include voice communications such as standard telephony applications, voice-over-Internet Protocol (VoIP) applications, local gaming, Internet gaming, email, instant messaging, multimedia messaging, web browsing, audio/video recording, audio/video playback, audio/video downloading, playing of streaming audio/video, office applications such as databases, spreadsheets, word processing, presentation creation and processing and other voice and data applications. In conjunction with these applications, the real-time data 126 includes voice, audio, video and multimedia applications including Internet gaming, etc. The non-real-time data 124 includes text messaging, email, web browsing, file uploading and downloading, etc.

In an embodiment of the present invention, the communication device 110 includes a wireless transceiver that includes one or more features or functions of the present invention.

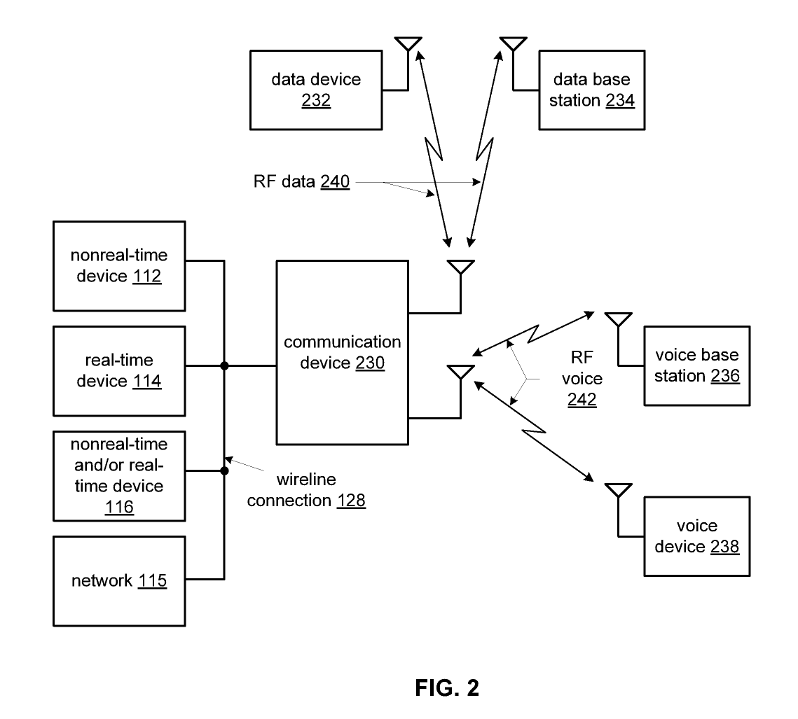

FIG. 2 is a schematic block diagram of an embodiment of another communication system in accordance with the present invention. In particular, FIG. 2 presents a communication system that includes many common elements of FIG. 1 that are referred to by common reference numerals. Communication device 230 is similar to communication device 110 and is capable of any of the applications, functions and features attributed to communication device 110, as discussed in conjunction with FIG. 1. However, communication device 230 includes two or more separate wireless transceivers for communicating, contemporaneously, via two or more wireless communication protocols with data device 232 and/or data base station 234 via RF data 240 and voice base station 236 and/or voice device 238 via RF voice signals 242.

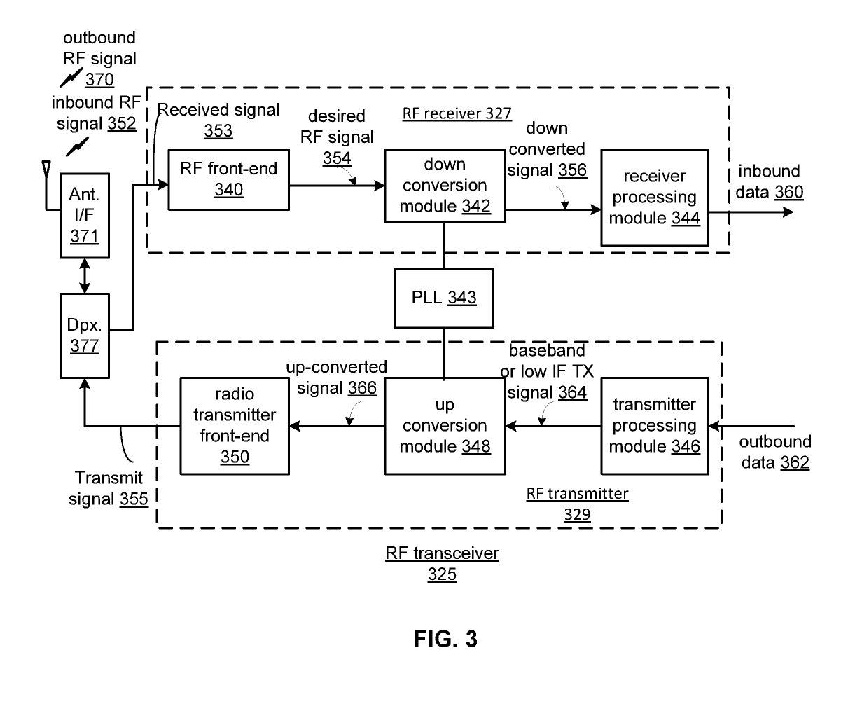

FIG. 3 is a schematic block diagram of an embodiment of a wireless transceiver 325 in accordance with the present invention. The RF transceiver 325 represents a wireless transceiver for use in conjunction with communication devices 110 or 230, base station 118, non-real-time device 120, real-time device 122, and non-real-time, real-time device 125, data device 232 and/or data base station 234, and voice base station 236 and/or voice device 238. RF transceiver 325 includes an RF transmitter 329, and an RF receiver 327. The RF receiver 327 includes a RF front end 340, a down conversion module 342 and a receiver processing module 344. The RF transmitter 329 includes a transmitter processing module 346, an up conversion module 348, and a radio transmitter front-end 350.

As shown, the receiver and transmitter are each coupled to an antenna through an antenna interface 371 and a diplexer (duplexer) 377, that couples the transmit signal 355 to the antenna to produce outbound RF signal 370 and couples inbound signal 352 to produce received signal 353. Alternatively, a transmit/receive switch can be used in place of diplexer 377.

In operation, the RF transmitter 329 receives outbound data 362. The transmitter processing module 346 packetizes outbound data 362 in accordance with a millimeter wave protocol or wireless telephony protocol, either standard or proprietary, to produce baseband or low intermediate frequency (IF) transmit (TX) signals 364 that includes an outbound symbol stream that contains outbound data 362. The baseband or low IF TX signals 364 may be digital baseband signals (e.g., have a zero IF) or digital low IF signals, where the low IF typically will be in a frequency range of one hundred kilohertz to a few megahertz. Note that the processing performed by the transmitter processing module 346 can include, but is not limited to, scrambling, encoding, puncturing, mapping, modulation, and/or digital baseband to IF conversion.

The up conversion module 348 includes a digital-to-analog conversion (DAC) module, a filtering and/or gain module, and a mixing section. The DAC module converts the baseband or low IF TX signals 364 from the digital domain to the analog domain. The filtering and/or gain module filters and/or adjusts the gain of the analog signals prior to providing it to the mixing section. The mixing section converts the analog baseband or low IF signals into up-converted signals 366 based on a transmitter local oscillation as provided by PLL 343.

The radio transmitter front end 350 includes a power amplifier and may also include a transmit filter module. The power amplifier amplifies the up-converted signals 366 to produce outbound RF signals 370, which may be filtered by the transmitter filter module, if included. The antenna structure transmits the outbound RF signals 370 via an antenna interface 371 coupled to an antenna that provides impedance matching and optional band pass filtration.

The RF receiver 327 receives inbound RF signals 352 via the antenna and antenna interface 371 that operates to process the inbound RF signal 352 into received signal 353 for the receiver front-end 340. In general, antenna interface 371 provides impedance matching of antenna to the RF front-end 340, optional band pass filtration of the inbound RF signal 352.

The down conversion module 342 includes a mixing section, an analog to digital conversion (ADC) module, and may also include a filtering and/or gain module. The mixing section converts the desired RF signal 354 into a down converted signal 356 that is based on a receiver local oscillation, such as an analog baseband or low IF signal. The ADC module converts the analog baseband or low IF signal into a digital baseband or low IF signal. The filtering and/or gain module high pass and/or low pass filters the digital baseband or low IF signal to produce a baseband or low IF signal 356 that includes an inbound symbol stream. Note that the ordering of the ADC module and filtering and/or gain module may be switched, such that the filtering and/or gain module is an analog module.

The receiver processing module 344 processes the baseband or low IF signal 356 in accordance with a millimeter wave protocol, either standard or proprietary, to produce inbound data 360 such as probe data received from a probe device or devices (not shown). The processing performed by the receiver processing module 344 can include, but is not limited to, digital intermediate frequency to baseband conversion, demodulation, demapping, depuncturing, decoding, and/or descrambling.

In one or more embodiments of the present invention, receiver processing module 344 and transmitter processing module 346 can be implemented via use of a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The associated memory may be a single memory device or a plurality of memory devices that are either on-chip or off-chip. Such a memory device may be a read-only memory, random access memory, volatile memory, non-volatile memory, static memory, dynamic memory, flash memory, and/or any device that stores digital information. Note that when the processing devices implement one or more of their functions via a state machine, analog circuitry, digital circuitry, and/or logic circuitry, the associated memory storing the corresponding operational instructions for this circuitry is embedded with the circuitry comprising the state machine, analog circuitry, digital circuitry, and/or logic circuitry.

While the processing module 344 and transmitter processing module 346 are shown separately, it should be understood that these elements could be implemented separately, together through the operation of one or more shared processing devices or in combination of separate and shared processing.

In another embodiment, the receiver and transmitter may share a multiple input multiple output (MIMO) antenna structure, diversity antenna structure, phased array or other controllable antenna structure that includes a plurality of antennas and other RF transceivers similar to RF transceiver 325. Each of these antennas may be fixed, programmable, and antenna array or other antenna configuration. Also, the antenna structure of the wireless transceiver may depend on the particular standard(s) to which the wireless transceiver is compliant and the applications thereof.

A phase-locked loop or phase lock loop (PLL) is a control system that generates an output signal whose phase is related to the phase of an input signal. While there are several differing types, it generally includes an electronic circuit consisting of a variable frequency oscillator (VCO) and a phase detector. The VCO generates a periodic signal. The phase detector compares the phase of that signal with the phase of the input periodic signal and adjusts the oscillator to keep the phases matched. A phase-locked loop can track an input frequency, or it can generate a frequency that is a multiple of the input frequency. These properties are used for computer clock synchronization, demodulation, and frequency synthesis, etc.

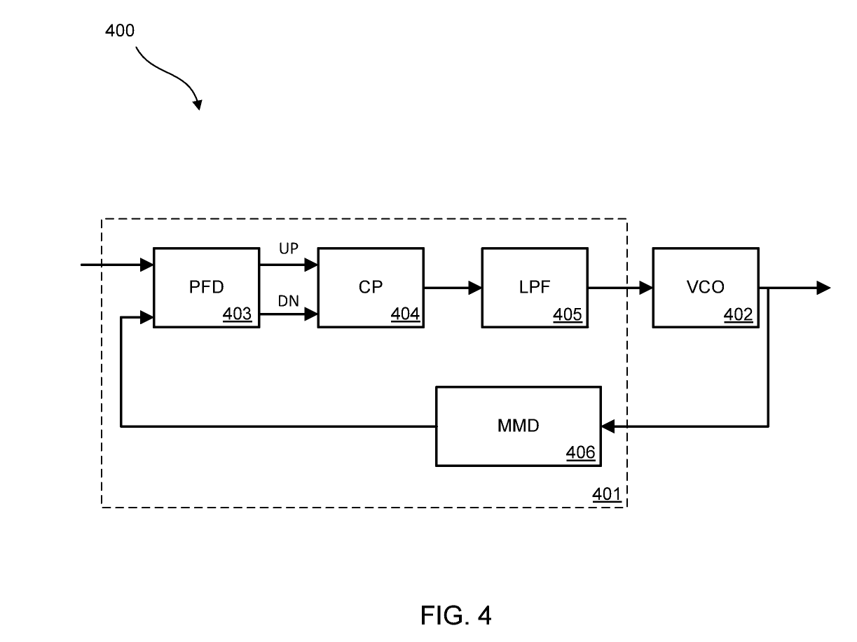

FIG. 4 illustrates a general PLL architecture diagram in accordance with the present disclosure. PLL 400 includes feed forward and feedback paths 401 coupled to voltage controlled oscillator (VCO) 402. The feed forward path includes phase frequency detector (PFD) 403, charge pump 404 and low pass filter (LPF) 405. The feedback path includes multiple modulus divider (MMD) 406. The PLL operates by comparing an input signal with a reference signal (feedback signal) to produce an error signal. The phase difference between the reference signal and the input signal is provided by PFD 403 in one of two signals, an up (UP) signal or a down (DN) signal depending on the error signal. The resultant signal controls switches for the current path into and out of PFD 403, causing charge pump 404 to increase or decrease the signal voltage for LPF 405. During each PLL cycle, the phase difference of the error signal is proportional to the time during which the corresponding switch is active making the phase difference directly dependent on the charge delivered. The signal is filtered by LPF 405 and the voltage of the signal tunes VCO 402. A feedback loop is provided having MMD 406 for dividing the output signal for feedback into PFD 403.

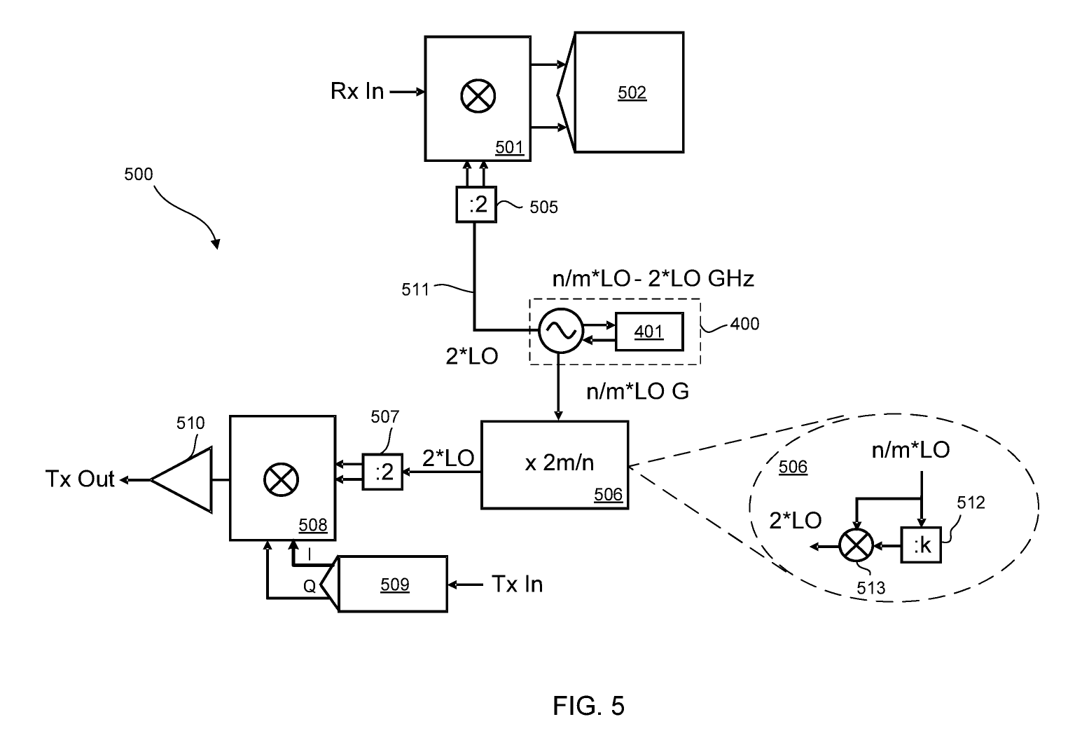

FIG. 5 illustrates an embodiment of a dual-band transceiver architecture in accordance with the present disclosure. Traditionally, to avoid pulling (i.e., local oscillator pulled off frequency), PLL 400 is not set to generate an oscillator output at or near the RF signal frequency or its harmonics. Instead, for example when the transceiver is in transmission mode (Tx), a local oscillator generator (LOGEN) circuit modifies the PLL oscillator output frequency to run at a fraction of the carrier signal. However, in the receive mode (Rx), the LOGEN circuit increases power consumption unnecessarily. As shown, FIG. 5 illustrates a transceiver architecture that uses the LOGEN 506 in Tx mode to avoid pulling, but bypasses (511) the LOGEN in the Rx mode to provide power savings.

Transceiver 500 includes a receive (Rx) processing chain for processing a received signal, for example, as received from an antenna (not shown). The received signal is down-converted by mixing a received signal (Rx In) in mixer 501 with a local oscillator (LO) signal generated by PLL 400. The analog-to-digital converter 502 converts the received baseband signal to a digital baseband signal for processing by a digital signal processor (DSP), not shown. As previously discussed, to avoid pulling, the PLL frequency is not set at the carrier frequency (or it's harmonics). In one or more embodiments, the PLL frequency is set at a multiple of the carrier frequency, for example two times, where the PLL frequency is 2LO. A divide by two (:2) circuit 505 reduces the 2LO frequency to a frequency substantially equal to LO which is input to mixer 501 for down-conversion.

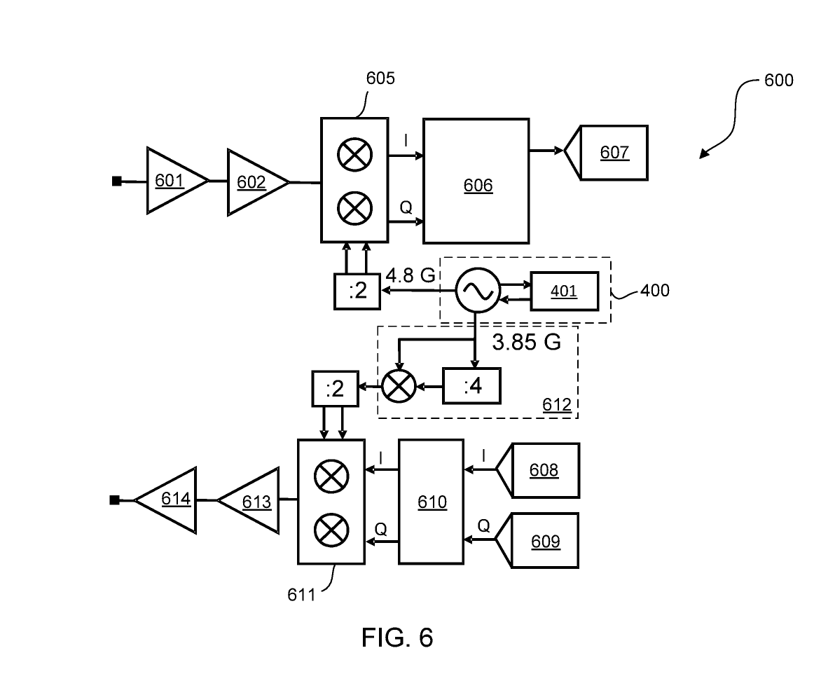

Transceiver 500 also includes a transmit (Tx) processing chain for processing a transmission signal to transmit, for example, through an antenna (not shown). The Tx signal (Tx In) is received as a digital baseband signal and converted to analog through DAC 509. The analog Tx signal is up-converted by mixer 508 with an input LO received from LOGEN 506. In the transmit mode, the PLL generates a fractional LO signal (n/m*LO, where n and m are integers). LOGEN 506 receives the fractionalized PLL signal and outputs an oscillation signal at twice the LO frequency (2*LO)—as further detailed in FIG. 6. A divide by two (:2) circuit 507 reduces the 2*LO frequency to a frequency substantially equal to LO which is input to mixer 508 for up-conversion.

In Tx mode, PLL 400 outputs a fractional LO phase locked signal. LOGEN circuit 506 multiplies the fractional LO phase locked signal so that the output signal of the LOGEN circuit is substantially 2*LO. The output signal from PLL 400 (fractional LO phase locked signal) is provided to both divider 512 and mixer 513 (see 506 breakout) to create the LOGEN output signal. For example, if n=4, m=3 and k=2, the mixer would add 4/3LO to (4/3LO divided by 2=4/6LO or 2/3LO). 4/3LO plus 2/3LO=6/3LO or 2*LO.

FIG. 6 illustrates an aspect embodiment of a Bluetooth transceiver with a PLL/LOGEN circuit in accordance with the present disclosure. In Rx mode, transceiver 600 includes, for example, power amplifiers 601 and 602 to receive and amplify received communication signals (Rx) from an antenna (not shown). The PLL 400 provides a phase locked signal that is set as a multiple of the carrier frequency. In this case the carrier frequency is 2.4 GHz and, for example, PLL multiplies the phase locked LO frequency by 2 to produce a 4.8 GHz output signal. The 4.8 GHz output signal is divided to return to the LO frequency (i.e., 2.4 GHz) and combined with the received signal by mixers 605. The received signal is down-converted, filtered by 2^{nd}-order complex base-pass filter 606, converted to digital by analog-to-digital converter 607 for processing by a DSP (not shown).

In Tx mode, a digital baseband signal (including in-phase (I) and quadrature (Q) components) is provided by the DSP for transmission. The digital baseband transmission signal is converted to analog by digital-to-analog converters 608 and 609, filtered by low-pass filter LPF 610 where it is combined by mixers 611 with the LO signal. Phase locked loop 400 provides a phase locked signal that is set at a fraction of the LO frequency (e.g., shown here at 3.85 GHz). LOGEN circuit 612 adds 3.85/4 to 3.85=4.8125 to substantially produce a 4.8 GHz LO signal=2*LO frequency. The LOGEN circuit 2*LO signal is divided by 2 (:2) to produce an output signal substantially at the LO frequency used as an input to up-convert the transmission signal (Tx including in-phase (I) and quadrature (Q) components) by mixers 611. The up-converted signal is amplified by pre-amplifier 613 and power amplifier 614 for signal transmission to antennas (not shown).

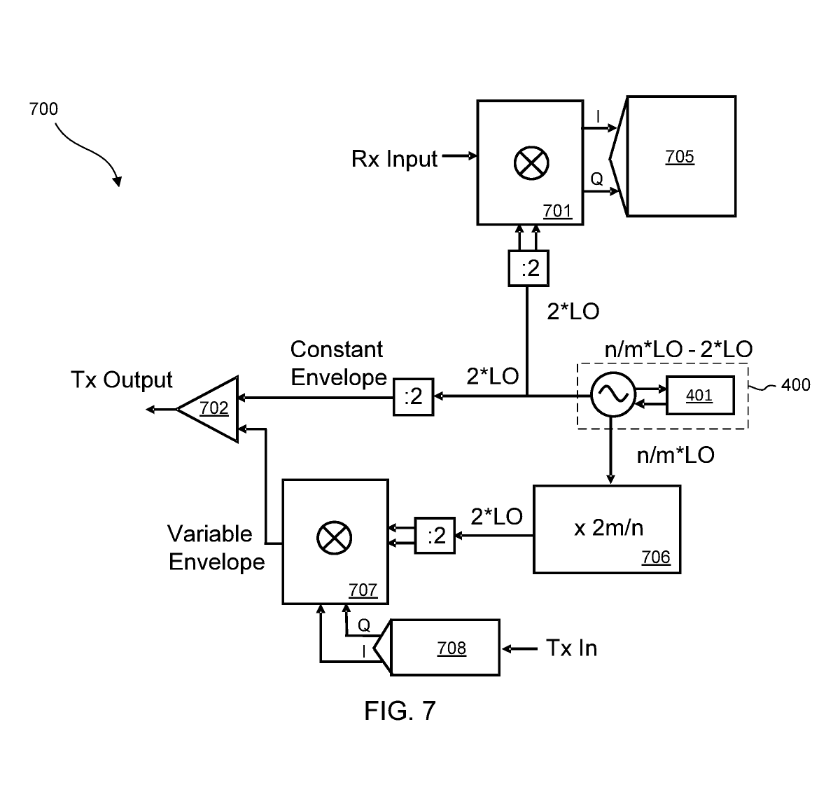

FIG. 7 illustrates an aspect embodiment of a dual-band transceiver including a dual path transmitter in accordance with the present disclosure. Transceiver 700 includes a receive (Rx) processing chain including a received signal (input), for example, as received from an antenna (not shown). The received signal is down-converted by mixing the received signal in mixer 701 with a local oscillator (LO) signal generated by PLL 400. The analog-to-digital converter 705 converts the received baseband signal to a digital baseband signal for processing by a DSP (not shown). As previously discussed, to avoid pulling, the PLL frequency is not set at the carrier frequency (or it's harmonics). In one or more embodiments, the PLL frequency is set at a multiple of the carrier frequency, such as two times (2*LO). A divide by two (:2) circuit reduces the 2*LO frequency to a frequency substantially equal to LO which is input to mixer 701 for down-conversion.

Transceiver 700 further includes a dual path transmitter. In Tx mode, a transmission signal (Tx) is processed by one of two pathways. In constant envelope mode, constant envelope transmissions are processed through a first path. In variable envelope mode, the transmission signal is processed through a second path. Transmission envelopes represent the upper and lower boundaries of an RF output signal. Points are tracked along the envelope and are synchronized in time with the corresponding points along with output signal. In a constant envelope mode, the upper and lower boundaries of the output signal are spaced at a constant value where the supply voltage modulates the output signal to maintain the constant spacing. Alternatively, in a non-constant envelope mode, the upper and lower boundaries of the output signal are variably spaced over time. The upper and lower spacing of the boundaries is determined by the LO frequency without modulating the output signal.

In constant envelope mode, a constant envelope is generated by PLL 400 and is set at a multiple of the carrier frequency, for example two times as shown, 2*LO frequency and includes a divide by 2 divider (:2) for input into pre-amp/power amp 702. In variable envelope mode, the Tx signal is received as a digital baseband signal and converted to analog through DAC 708. The analog baseband Tx signal is up-converted by mixer 707 with an input LO received from LOGEN 706. In the transmit mode, the PLL generates a fractional LO signal (n/m*LO, where n and m are integers). LOGEN 706 receives the fractionalized PLL signal and outputs an oscillation signal at a multiple of LO, for example, twice the LO frequency (2*LO). A divide by two (:2) circuit reduces the 2*LO frequency to a frequency substantially equal to LO which is input to mixer 707 for up-conversion. The upconverted Tx signal is output to pre-amp/power amp 702 for transmission through an antenna (not shown).

The multiple modes of operation provided by the transceiver not only reduce the current in Rx mode, but it also reduces the Tx current when in constant envelope mode due to the elimination of the LOGEN circuit from the processing path.

In yet another embodiment, a dual-band transmitter that uses a PLL running at RF or a multiple of RF without a conventional LOGEN circuit. The dual-band transmitter operates in a constant envelope mode or a non-constant envelope mode using the same PLL.

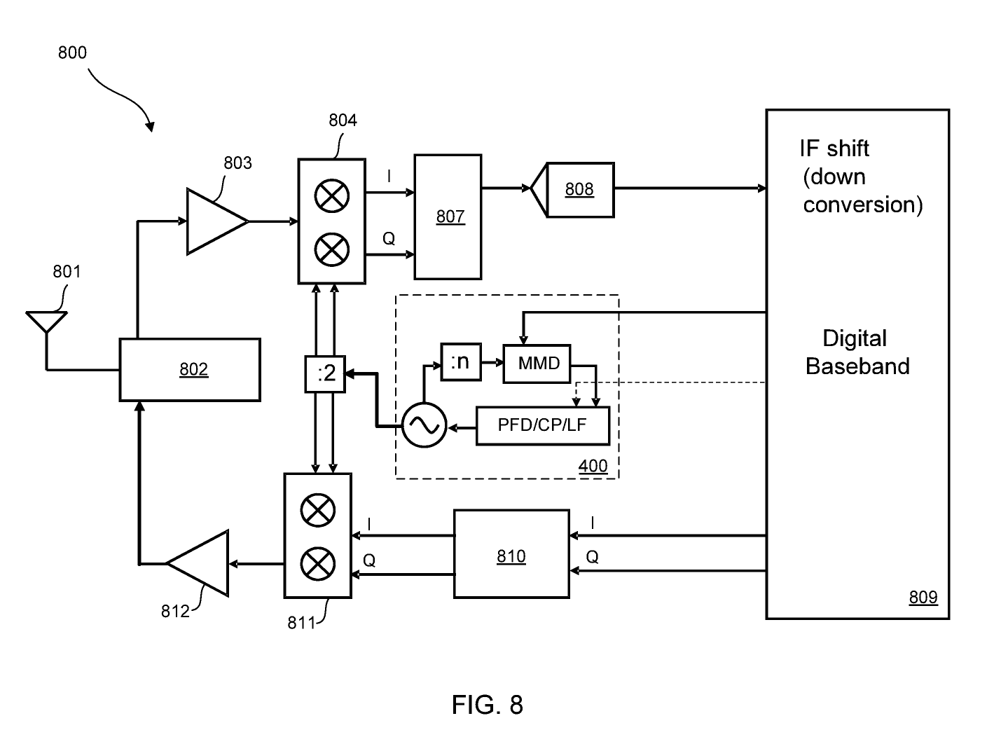

FIG. 8 illustrates another embodiment of transceiver architecture with a single LO for frequency-division duplexing (FDD) in accordance with the present disclosure. Transceiver 800 includes antenna 801 for concurrent reception and transmission of communication signals in separated bands (e.g., separation of 20 MHz) to/from the transceiver. Duplexer 802 (for filtering multiple signals to allow for bi-directional communication over a single path) feeds the transmission path and reception paths to/from antenna 801. The received signal is amplified by amplifier 803 where the received signal is down-converted to an intermediate frequency (IF) by mixer 804, bandpass filtered by bandpass filter (BPF) 807 and converted to digital by analog-to-digital converter 808. The down-converted IF signal is further processed by digital signal processor (DSP) 809 to digitally down-convert digital baseband (e.g., a 20 MHz down-conversion). The received signal is down-converted to IF by combining the received signal with LO frequency produced by PLL 400. PLL 400 generates a signal at a multiple of the carrier frequency, for example, at twice the LO frequency where the signal is divided (:2) to produce the LO frequency that is mixed with the received signal to produce an IF communication signal.

In transmission mode, a digital baseband transmission signal from DSP 909 (including baseband in-phase (I) and quadrature (Q) components) is converted to an analog signal and low-pass filtered by DAC/LPF 810. The filtered analog transmission signal (Tx) is up-converted in mixers 811 with a multiple of the LO frequency produced by PLL 400. The up-converted transmission signal is amplified by power amplifier 812 and transmitted through antenna 801 via duplexer 802.

For communication networks utilizing high RF signals, it is common for receive communications and transmit communications to interfere with one another. The transceiver architecture provided by transceiver 800 reduces potential interference between the concurrent signals using PLL 400. PLL 400 provides for Cartesian feedback of the transceiver, and more specifically the transmitter of the transceiver. The baseband signal components (in-phase (I) and quadrature (Q)) provided by DSP 809 modulate the carrier frequency before power amplification of the signal. The modulated signal is fed back through for demodulation for linearization. PLL 400 generates a local oscillator signal at a specific frequency (a multiple of the carrier frequency). DSP 809 feeds the baseband signal to the PLL to determine the phase of the baseband signal. The local oscillator signal phase is locked (matched) to the baseband signal provided by DSP 809. PLL generates a phase locked signal that is a multiple of the carrier signal. By using a multiple of the carrier frequency, interference between the concurrent transmission and receiving communications is avoided.

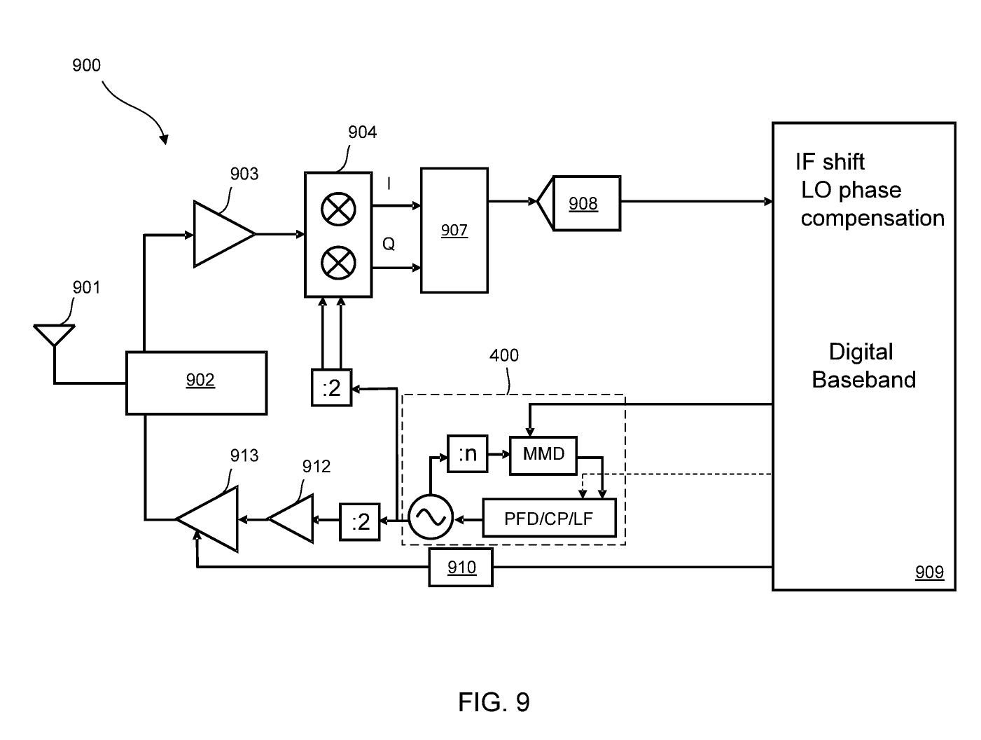

FIG. 9 illustrates another embodiment of transceiver architecture with a single LO for frequency-division duplexing (FDD) in accordance with the present disclosure. Transceiver 900 provides for polar feedback for wide bandwidth operations. Similar to Cartesian feedback (FIG. 8), polar feedback is a baseband feedback scheme that accounts for amplitude and phase of the baseband signal. Transceiver 900 includes antenna 901 for reception and transmission to/from the transceiver. Duplexer 902 feeds the transmission path and reception path to/from antenna 901. The received signal is amplified by amplifier 903 where the received signal is down-converted to an intermediate frequency (IF) by mixer 904, filtered by baseband filter 907 and converted to an analog IF communications signal by analog-to-digital converter 908. The down-converted IF signal is processed by DSP 909 where it is digitally phase adjusted.

The transmission signal is converted from DSP 909 by DAC 910 to modulate power amplifier 913. PLL 400 produces a local oscillator signal at a specific frequency which is a multiple of the carrier frequency (e.g., 2*LO). DSP 909 sends the baseband signal to PLL 400 to determine the phase of the baseband signal. The local oscillator signal phase is locked (matched) to the baseband signal provided by DSP 909. PLL 400 generates a phase locked signal that is a multiple of the carrier signal and includes a fractional feedback loop including divide by n circuit (:n) and multi-modulus divider MMD. By using a multiple of the carrier frequency, interference between the concurrent transmission and receiving communication signals is avoided.

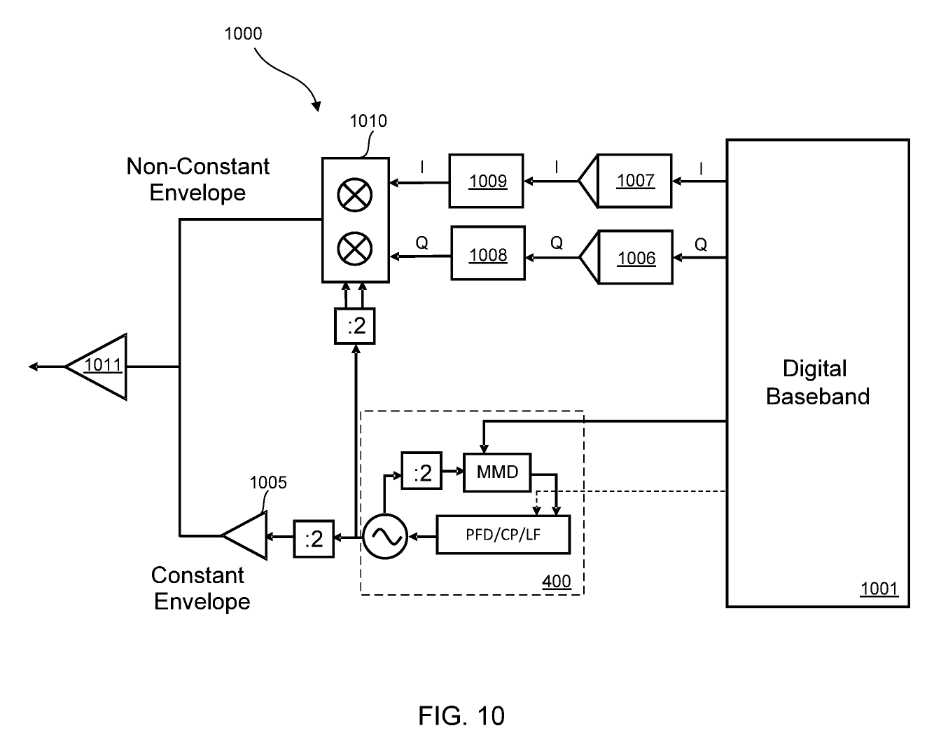

FIG. 10 illustrates a dual path transmitter for constant envelope and non-constant envelope modes in accordance with the present disclosure. Transmitter 1000 includes two transmission modes: one transmission mode operating in non-constant envelope and one transmission mode operating with a constant envelope. In the constant envelope mode, a digital signal is produced by DSP 1001 to MMD of PLL 400 to lock the phase of the digital baseband signal. The modulated digital signal is combined with a multiple of the LO signal (e.g., 2*LO). The output signal is divided by the multiple (e.g., ;2) and amplified by pre-power amplifier 1005 and power amplifier 1011 for transmission through an antenna not shown. In one embodiment, transmitter 1000 is part of a transceiver. In the constant envelope mode, the circuit elements of the non-constant envelope path are powered down to save power.

In non-constant envelope mode, a digital baseband signal (including in-phase (I) and quadrature (Q) components) is provided by the DSP 1001 for transmission. The digital baseband transmission signal is converted to analog by digital-to-analog converters 1006 and 1007 and filtered by BPFs 1008 and 1009 and upconverted by mixers 1010 with the LO signal. Phase locked loop 400 provides a phase locked signal to that is set at a multiple of the carrier frequency (e.g., shown here at 2*LO). The PLL 400 2*LO output signal is divided by 2 (:2) to produce an output signal substantially at the LO frequency used as an input to up-convert the transmission signal (Tx including in-phase (I) and quadrature (Q) components) by mixers 1010. The up-converted signal is amplified by power amplifier 1011 for signal transmission to one or more antennas (not shown). In the non-constant envelope mode, the pre-amplifier 1005 of the constant envelope path is powered down to save power.

In one or more embodiments the technology described herein the wireless connection can communicate in accordance with a wireless network protocol such as Wi-Fi, WiHD, NGMS, IEEE 802.11a, ac, b, g, n, or other 802.11 standard protocol, Bluetooth, Ultra-Wideband (UWB), WIMAX, LTE or other wireless network protocol, a wireless telephony data/voice protocol such as Global System for Mobile Communications (GSM), General Packet Radio Service (GPRS), Enhanced Data Rates for Global Evolution (EDGE), Personal Communication Services (PCS), or other mobile wireless protocol or other wireless communication protocol, either standard or proprietary. Further, the wireless communication path can include separate transmit and receive paths that use separate carrier frequencies and/or separate frequency channels. Alternatively, a single frequency or frequency channel can be used to bi-directionally communicate data to and from the mobile communications device.

Throughout the specification, drawings and claims various terminology is used to describe the various embodiments. As may be used herein, the terms “carrier frequency” and “local oscillator (LO)” refer to substantially common frequency values. As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, wavelengths, distance between antennas and circuit variations. Such relativity between items ranges from a difference of a few percent to magnitude differences. As may also be used herein, the term(s) “operably coupled to”, “coupled to”, and/or “coupling” includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item. As may be used herein, the term “compares favorably”, indicates that a comparison between two or more items, signals, etc., provides a desired relationship.

In an embodiment of the technology described herein, receiver and transmitter processing modules are implemented via use of a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. In some embodiments, the associated memory is a single memory device or a plurality of memory devices that are either on-chip or off-chip. Such a memory device includes a read-only memory, random access memory, volatile memory, non-volatile memory, static memory, dynamic memory, flash memory, and/or any device that stores digital information. Note that when the processing devices implement one or more of their functions via a state machine, analog circuitry, digital circuitry, and/or logic circuitry, the associated memory storing the corresponding operational instructions for this circuitry is embedded with the circuitry comprising the state machine, analog circuitry, digital circuitry, and/or logic circuitry.

As may also be used herein, the terms “processor”, “processor module”, “processing module”, “processing circuit”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

The technology as described herein has been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed technology described herein. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed technology described herein. One of average skill in the art will also recognize that the functional building blocks, and other illustrative blocks, modules and components herein, can be implemented as illustrated or by discrete components, application specific integrated circuits, processors executing appropriate software and the like or any combination thereof.

The technology as described herein may have also been described, at least in part, in terms of one or more embodiments. An embodiment of the technology as described herein is used herein to illustrate an aspect thereof, a feature thereof, a concept thereof, and/or an example thereof. A physical embodiment of an apparatus, an article of manufacture, a machine, and/or of a process that embodies the technology described herein may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

While particular combinations of various functions and features of the technology as described herein have been expressly described herein, other combinations of these features and functions are likewise possible. The technology as described herein is not limited by the particular examples disclosed herein and expressly incorporates these other combinations.

What is claimed is:

1. A transceiver comprising:
a receiver processing chain including at least a down-converter;
a transmission processing chain including at least an up-converter;
a phase lock loop coupled to both the down-converter and the up-converter; and
wherein the phase lock loop is configured, in a receive mode, to generate a first output oscillation signal at a multiple of a carrier frequency and, in a transmit mode, to generate a second output oscillation signal at a fraction of the carrier frequency.

2. The transceiver according to claim 1, wherein the phase lock loop is further configured to generate the first output oscillation to have a frequency that is two times the frequency of the carrier frequency.

3. The transceiver according to claim 1 further comprising a divider to reduce the first output oscillation signal by the multiple and coupling to the down-converter.

4. The transceiver according to claim 1 further comprising circuitry to convert the fraction of the carrier frequency to a third output signal, which is a multiple of the carrier frequency.

5. The transceiver according to claim 4 further comprising a divider to reduce the third output signal by the multiple and coupling to the up-converter.

6. The transceiver according to claim 1, wherein the transceiver further comprises Bluetooth circuitry for facilitating Bluetooth communications.

7. The transceiver according to claim 1 further comprising the transmission processing chain comprising a first and second transmission path, the first transmission path generating a constant envelope from the first output oscillation signal and the second path generating a variable envelope using the second output oscillation signal.

8. The transceiver according to claim 7, wherein the first and second paths are further configured to operate independently of each other and wherein one or more circuit elements of the second path are powered down during operation of the first path and one or more circuit elements of the first path are powered down during operation of the second path.

9. The transceiver according to claim 1, wherein the down-converter is configured to down-convert a received signal to an intermediate frequency signal.

10. The transceiver according to claim 9, further comprising a digital signal processor configured to digitally down-convert the intermediate frequency signal.

11. The transceiver according to claim 9, further comprising a digital signal processor configured to digitally phase adjust the intermediate frequency signal.

12. A transceiver comprising:
a receiver processing chain including at least a down-converter;
a first transmission processing chain generating a constant envelope transmission signal;
a second transmission processing chain including at least an up-converter and generating a variable envelope;
a phase lock loop coupled to the receiver and first and second transmission processing chains; and
wherein the phase lock loop is configured in: a receive mode to generate a first output oscillation signal at a multiple of a carrier frequency; a first transmit mode to generate the constant envelope using the multiple of the carrier frequency; and a second transmit mode generating the variable envelope using a second output oscillation signal at a fraction of the carrier frequency.

13. The transceiver according to claim 12, wherein the phase lock loop is further configured to generate the first output oscillation to have a frequency that is two times the frequency of the carrier frequency.

14. The transceiver according to claim 12 further comprising a divider to reduce the first output oscillation signal by the multiple and coupling to the down-converter.

15. The transceiver according to claim 12, wherein the a second transmission processing chain further includes a local oscillator generator (LOGEN) to convert the fraction of the local oscillator frequency to a third output signal which is a multiple of the carrier frequency.

16. The transceiver according to claim 15 further comprising a divider to reduce the third output signal by the multiple and coupling to the up-converter.

17. The transceiver according to claim 12, wherein the transceiver further comprises Bluetooth circuitry for facilitating Bluetooth communications.

18. A frequency-division duplex transceiver comprising:
a duplexer for receiving bi-directional communication signals including a receive signal and transmit signal;
a receiver processing chain including at least a down-converter;
a transmission processing chain including at least an up-converter;
a phase lock loop shared by the receiver and transmission processing chains, the phase lock loop configured to generate an output oscillation signal at a multiple of the carrier frequency;
a digital signal processor; and
wherein the transceiver is configured to down-convert the receive signal to an intermediate frequency followed by the digital signal processor digitally down-converting the intermediate frequency and up-convert the transmit signal.

19. The frequency-division duplex transceiver according to claim 18, further comprising the digital signal processor configured to digitally phase adjust the intermediate frequency signal.

20. The frequency-division duplex transceiver according to claim 18, wherein the frequency-division duplex transceiver further comprises Bluetooth circuitry for facilitating Bluetooth communications.
